(19) United States
(12) Patent Application Publication
(10) Pub. No.: US 2024/0188452 A1
(43) Pub. Date: Jun. 6, 2024

(54) JOINED BODY AND METHOD FOR PRODUCING JOINED BODY

(71) Applicant: SUMITOMO ELECTRIC INDUSTRIES, LTD., Osaka (JP)

(72) Inventors: Kotaro OHKI, Osaka (JP); Tatsuoki NAGAISHI, Osaka (JP)

(73) Assignee: SUMITOMO ELECTRIC INDUSTRIES, LTD., Osaka (JP)

(21) Appl. No.: 18/286,134

(22) PCT Filed: Jan. 6, 2022
(86) PCT No.: PCT/JP2022/000243

§ 371 Date: Oct. 8, 2023

(30) Foreign Application Priority Data
Apr. 13, 2021 (JP) 2021-067673

(51) Int. Cl. H10N 60/01; H10N 60/12; H10N 60/85

(52) U.S. Cl. CPC H10N 60/0941; H10N 60/0661; H10N 60/124; H10N 60/0464; H10N 60/857

(57) ABSTRACT

A joined body includes: a first superconducting layer, a barrier layer arranged on the first superconducting layer, and a second superconducting layer arranged on the barrier layer. The first superconducting layer, the barrier layer, and the second superconducting layer are formed of a REBCO. A leak current from one of the first superconducting layer and the second superconducting layer to the other of the first superconducting layer and the second superconducting layer is blocked by the barrier layer.

### TECHNICAL FIELD

The present disclosure relates to a joined body and a method for producing a joined body. The present application claims a priority based on Japanese Patent Application No. 2021-067673, filed on Apr. 13, 2021. The entire content described in the Japanese patent application is incorporated by reference herein.

### BACKGROUND ART

For example, PTL 1 (Japanese Patent Laying-Open No. H10-65226) describes a joined body. The joined body described in PTL 1 has a first superconducting layer, a non-superconducting layer, and a second superconducting layer. The non-superconducting layer is arranged on the first superconducting layer. The second superconducting layer is arranged on the non-superconducting layer.

The first superconducting layer and the second superconducting layer are formed of YBa₂Cu₃Oₓ. The non-superconducting layer is formed of PrBa₂Cu₃Oₓ. According to this, the first superconducting layer, the second superconducting layer, and the non-superconducting layer constitute a Josephson junction.

### CITATION LIST

### Patent Literature

PTL 1: Japanese Patent Laying-Open No. H10-65226

### SUMMARY OF INVENTION

A joined body of the present disclosure comprises: a first superconducting layer; a barrier layer arranged on the first superconducting layer; and a second superconducting layer arranged on the barrier layer. The first superconducting layer, the barrier layer, and the second superconducting layer are formed of a REBCO. A leak current from one of the first superconducting layer and the second superconducting layer to the other of the first superconducting layer and the second superconducting layer is blocked by the barrier layer.

A method for producing a joined body of the present disclosure comprises: forming a first superconducting layer on a first substrate; forming a second superconducting layer on a second substrate; forming a fine crystal layer on any one of the first superconducting layer and the second superconducting layer; and heating the first substrate and the second substrate in a state where the first substrate and the second substrate are held so that the fine crystal layer is sandwiched between the first superconducting layer and the second superconducting layer. The first superconducting layer and the second superconducting layer are formed of a REBCO. The fine crystal layer is formed of a polycrystal REBCO.

### BRIEF DESCRIPTION OF DRAWINGS

FIG. 1 is a sectional view of a joined body 100.

FIG. 2 is a process flowchart that describes a method for producing joined body 100.

FIG. 3 is a sectional view of a second substrate 30 after performing a fine crystal layer forming step S3.

FIG. 4 is a sectional view of a joined body 200.

FIG. 5 is a sectional view of a joined body 100 according to a modified example.

FIG. 6 is a sectional view of a joined body 300.

### DETAILED DESCRIPTION

### Problem to be Solved by the Present Disclosure

In the step of producing the joined body described in PTL 1, the non-superconducting layer is epitaxially grown on the first superconducting layer. In the method for producing a joined body described in PTL 1, the second superconducting layer is then epitaxially grown on the non-superconducting layer. Thus, yttrium in the first superconducting layer and yttrium in the second superconducting layer diffuse into the non-superconducting layer when the second superconducting layer is epitaxially grown.

Thus, in the joined body described in PTL 1, yttrium diffused into the non-superconducting layer causes the non-superconducting layer to have at least partially superconductivity to form a path where a superconductive current flows in the non-superconducting layer, which flows a leak current between the first superconducting layer and the second superconducting layer. That is, in the joined body described in PTL 1, pinholes formed in the non-superconducting layer flow the leak current between the first superconducting layer and the second superconducting layer. When the leak current flows between the first superconducting layer and the second superconducting layer, the Josephson effect is not exhibited.

The present disclosure have been made in view of the above problems in the conventional art. More specifically, the present disclosure provides: a joined body that can block the leak current between the first superconducting layer and the second superconducting layer; and a method for producing a joined body.

### Advantageous Effect of the Present Disclosure

According to the joined body and method for producing a joined body of the present disclosure, the leak current between the first superconducting layer and the second superconducting layer can be blocked.

### DESCRIPTION OF EMBODIMENTS

First, embodiments of the present disclosure will be listed and described.

(1) A joined body according to an embodiment comprises: a first superconducting layer; a barrier layer arranged on the first superconducting layer; and a second superconducting layer arranged on the barrier layer. The first superconducting layer, the barrier layer, and the second superconducting layer are formed of a REBCO. A leak current from one of the first superconducting layer and the second superconducting layer to the other of the first superconducting layer and the second superconducting layer is blocked by the barrier layer.

According to the joined body of (1), the leak current between the first superconducting layer and the second superconducting layer can be blocked.

(2) In the joined body of (1), a rare earth element in the REBCO that constitutes the first superconducting layer and the second superconducting layer may be selected so that the first superconducting layer and the second superconducting layer exhibit superconductivity. A rare earth element in the REBCO that constitutes the barrier layer may be selected so that the barrier layer does not exhibit superconductivity.

According to the joined body of (2), changing a component of the rare earth element in the REBCO that constitutes the barrier layer can block the leak current between the first superconducting layer and the second superconducting layer.

(3) In the joined body of (2), the rare earth element in the REBCO that constitutes the first superconducting layer and the second superconducting layer may be at least one or more elements selected from the group consisting of yttrium, lanthanum, neodymium, samarium, europium, gadolium, dysprosium, holmium, erbium, thulium, lutetium, and ytterbium. The rare earth element in the REBCO that constitutes the barrier layer may be praseodymium.

According to the joined body of (3), changing a component of the rare earth element in the REBCO that constitutes the barrier layer can block the leak current between the first superconducting layer and the second superconducting layer.

(4) In the joined body of (2) or (3), the barrier layer may be epitaxially grown from the first superconducting layer and the second superconducting layer.

According to the joined body of (4), changing a component of the rare earth element in the REBCO that constitutes the barrier layer can block the leak current between the first superconducting layer and the second superconducting layer.

(5) In the joined body of (1), the barrier layer may have a first layer arranged on the first superconducting layer and a second layer arranged on the first layer. A c-axis direction of a REBCO that constitutes the first layer may be along a c-axis direction of a REBCO that constitutes the second layer. An a-axis direction of the REBCO that constitutes the first layer may differ from an a-axis direction of the REBCO that constitutes the second layer.

According to the joined body of (5), setting the a-axis direction of the REBCO that constitutes the first layer and the a-axis direction of the REBCO that constitutes the second layer to be different can block the leak current between the first superconducting layer and the second superconducting layer.

(6) In the joined body of (5), the first layer may be epitaxially grown from the first superconducting layer, and the second layer may be epitaxially grown from the second superconducting layer. A c-axis direction of the REBCO that constitutes the first superconducting layer may be along a c-axis direction of the REBCO that constitutes the second superconducting layer. An a-axis direction of the REBCO that constitutes the first superconducting layer may differ from an a-axis direction of the REBCO that constitutes the second superconducting layer.

According to the joined body of (6), setting the a-axis direction of the REBCO that constitutes the first superconducting layer and the a-axis direction of the REBCO that constitutes the second superconducting layer to be different can set the a-axis direction of the REBCO that constitutes the first layer and the a-axis direction of the REBCO that constitutes the second layer to be different, and thereby the leak current between the first superconducting layer and the second superconducting layer can be blocked.

(7) In the joined body of (5) or (6), a rare earth element in the REBCO that constitutes the first superconducting layer, the second superconducting layer, and the barrier layer may be at least one or more elements selected from the group consisting of yttrium, lanthanum, neodymium, samarium, europium, gadolium, dysprosium, holmium, erbium, thulium, lutetium, and ytterbium.

According to the joined body of (7), the leak current between the first superconducting layer and the second superconducting layer can be blocked without setting the rare earth element in the REBCO that constitutes the first superconducting layer and the second superconducting layer to be different from the rare earth element in the REBCO that constitutes the barrier layer.

(8) The joined body of (1) to (7) may further comprise a substrate. The first superconducting layer may be arranged on the substrate. The substrate may be formed of at least one or more oxides selected from cerium oxide, yttria-stabilized zirconia, lanthanum manganate, sapphire, or strontium titanate.

According to the joined body of (8), increasing oxygen permeability of the substrate facilitates supplying oxygen to the first superconducting layer through the substrate.

(9) The joined body of (1) to (7) may further comprise: a metal substrate; and an intermediate layer arranged on the meal substrate. The first superconducting layer may be arranged on the intermediate layer. The intermediate layer may be formed of at least one or more oxides selected from cerium oxide, yttria-stabilized zirconia, lanthanum manganate, sapphire, or strontium titanate.

According to the joined body of (9), increasing oxygen permeability of the intermediate layer facilitates supplying oxygen to the first superconducting layer through the intermediate layer.

(10) The joined body of (1) to (7) may further comprise a substrate. The first superconducting layer may be arranged on the substrate. A c-axis direction of the REBCO that constitutes the first superconducting layer may be along any one of a direction of a main surface of the substrate on a side of the first superconducting layer and a direction of a normal line of the main surface.

According to the joined body of (10), any of an a-axis oriented film and a c-axis oriented film can be used as the substrate on which the first superconducting layer is formed.

(11) A method for producing a joined body according to an embodiment comprises: forming a first superconducting layer on a first substrate; forming a second superconducting layer on a second substrate; forming a fine crystal layer on any one of the first superconducting layer and the second superconducting layer; and heating the first substrate and the second substrate in a state where the first substrate and the second substrate are held so that the fine crystal layer is sandwiched between the first superconducting layer and the second superconducting layer. The first superconducting layer and the second superconducting layer are formed of a REBCO. The fine crystal layer is formed of a polycrystal REBCO.

According to the method for producing a joined body of (11), the leak current between the first superconducting layer and the second superconducting layer can be blocked.

(12) The method for producing a joined body of (10), in heating the first substrate and the second substrate, at least part of the fine crystal layer may form a liquid phase.

According to the method for producing a joined body of (12), shortening a time of the heat treatment can more certainly block the leak current between the first superconducting layer and the second superconducting layer.

### DETAIL OF EMBODIMENTS OF THE PRESENT DISCLOSURE

With reference to the drawings, a detail of embodiments of the present disclosure will be then described. In the following drawings, same or corresponding parts are followed by a same reference sign, and an overlapping description is not repeated.

### First Embodiment

A joined body according to the first embodiment will be described. Hereinafter, the joined body according to the first embodiment is referred to as a joined body 100.

### <Constitution of Joined Body 100>

Hereinafter, constitution of joined body 100 will be described.

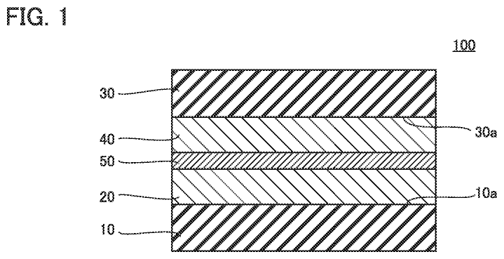

FIG. 1 is a sectional view of joined body 100. As illustrated in FIG. 1, joined body 100 has a first substrate 10, a first superconducting layer 20, a second substrate 30, a second superconducting layer 40, and a barrier layer 50. Joined body 100 may not have second substrate 30.

First substrate 10 has a first main surface 10a. First substrate 10 is preferably formed of at least one oxide selected from the group consisting of cerium oxide, yttria-stabilized zirconia, lanthanum manganate, sapphire, or strontium titanate, for example. That is, first substrate 10 is preferably formed of a material having oxygen permeability.

First superconducting layer 20 is arranged on first main surface 10a. First superconducting layer 20 is formed of a REBCO. The REBCO is an oxide superconductive substance represented by REBa₂Cu₃Oₓ. Here, RE represents a rare earth element. The rare earth element in the REBCO that constitutes first superconducting layer 20 is at least one or more elements selected from the group consisting of yttrium, lanthanum, neodymium, samarium, europium, gadolium, dysprosium, holmium, erbium, thulium, lutetium, and ytterbium. That is, the rare earth element in the REBCO that constitutes first superconducting layer 20 is selected so that first superconducting layer 20 exhibits superconductivity.

A direction of a c-axis of the REBCO that constitutes first superconducting layer 20 is along a direction of a normal line of first main surface 10a, for example. Hereinafter, the direction of the c-axis of the REBCO may be referred to as the c-axis direction. The c-axis direction of the REBCO that constitutes first superconducting layer 20 may be along the direction of first main surface 10a.

Second substrate 30 has a second main surface 30a. Second main surface 30a is directed to a side of first main surface 10a. Second substrate 30 is preferably formed of at least one oxide selected from the group consisting of cerium oxide, yttria-stabilized zirconia, lanthanum manganate, sapphire, or strontium titanate, for example. That is, second substrate 30 is preferably formed of a material having oxygen permeability.

Second superconducting layer 40 is arranged on second main surface 30a. Second superconducting layer 40 is formed of a REBCO. The rare earth element in the REBCO that constitutes second superconducting layer 40 is at least one or more elements selected from the group consisting of yttrium, lanthanum, neodymium, samarium, europium, gadolium, dysprosium, holmium, erbium, thulium, lutetium, and ytterbium. That is, the rare earth element in the REBCO that constitutes second superconducting layer 40 is selected so that second superconducting layer 40 exhibits superconductivity.

A c-axis direction of the REBCO that constitutes second superconducting layer 40 is along a direction of a normal line of second main surface 30a, for example. The c-axis direction of the REBCO that constitutes second superconducting layer 40 may be along the direction of second main surface 30a. The c-axis direction of the REBCO that constitutes second superconducting layer 40 is along the c-axis direction of the REBCO that constitutes first superconducting layer 20. A direction of an a-axis of the REBCO that constitutes second superconducting layer 40 is along an a-axis direction of the REBCO that constitutes first superconducting layer 20. Hereinafter, the direction of the a-axis of the REBCO may be referred to as the a-axis direction.

Barrier layer 50 is sandwiched between first superconducting layer 20 and second superconducting layer 40. From another viewpoint, this can be mentioned that barrier layer 50 is on first superconducting layer 20 and second superconducting layer 40 is on barrier layer 50.

Barrier layer 50 is formed of a REBCO. A rare earth element in the REBCO that constitutes barrier layer 50 is praseodymium, for example. That is, the rare earth element in the REBCO that constitutes barrier layer 50 is selected so that barrier layer 50 does not exhibit superconductivity. A content of a rare earth element other than praseodymium in the REBCO that constitutes barrier layer 50 is, for example, 1 atom % or less. A density of pinholes in barrier layer 50 is, for example, 5% or less. First superconducting layer 20, second superconducting layer 40, and barrier layer 50 constitute a Josephson junction. From another viewpoint, this can be mentioned that joined body 100 is a Josephson joined body.

An a-axis direction of the REBCO that constitutes barrier layer 50 is along the a-axis direction of the REBCO that constitutes first superconducting layer 20. A c-axis direction of the REBCO that constitutes barrier layer 50 is along the c-axis direction of the REBCO that constitutes first superconducting layer 20. The a-axis direction of the REBCO that constitutes barrier layer 50 is along the a-axis direction of the REBCO that constitutes second superconducting layer 40. The c-axis direction of the REBCO that constitutes barrier layer 50 is along the c-axis direction of the REBCO that constitutes second superconducting layer 40. That is, barrier layer 50 is epitaxially grown from first superconducting layer 20 and second superconducting layer 40.

A thickness of barrier layer 50 is smaller than a thickness of first superconducting layer 20 and a thickness of second superconducting layer 40. Barrier layer 50 is, for example, 100 nm or less.

### <Method for Producing Joined Body 100>

Hereinafter, a method for producing joined body 100 will be described.

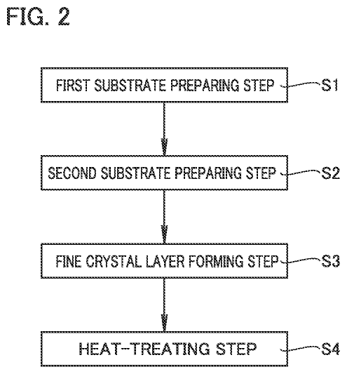

FIG. 2 is a process flowchart that describes a method for producing joined body 100. The method for producing joined body 100 comprises: a first substrate preparing step S1; a second substrate preparing step S2; a fine crystal layer forming step S3; and a heat-treating step S4, as illustrated in FIG. 2.

In first substrate preparing step S1, first substrate 10 is firstly prepared. In first substrate preparing step S1, first superconducting layer 20 is secondly formed on first main surface 10a. First superconducting layer 20 is formed by a metal organic deposition (MOD) method, for example. The rare earth element in the REBCO that constitutes first superconducting layer 20 is selected so that first superconducting layer 20 exhibits superconductivity, as noted above. A temperature in forming first superconducting layer 20 is, for example, 750° C. or more and 840° C. or less. The c-axis direction of the REBCO that constitutes first superconducting layer 20 is, for example, along a direction of first main surface 10a or along a direction of the normal line of first main surface 10a.

In second substrate preparing step S2, second substrate 30 is firstly prepared. In second substrate preparing step S2, second superconducting layer 40 is secondly formed on second main surface 30a. Second superconducting layer 40 is formed by an MOD method, for example. The rare earth element in the REBCO that constitutes second superconducting layer 40 is selected so that second superconducting layer 40 exhibits superconductivity, as noted above. A temperature in forming second superconducting layer 40 is, for example, 750° C. or more and 840° C. or less. The c-axis direction of the REBCO that constitutes second superconducting layer 40 is, for example, along a direction of second main surface 30a or along a direction of the normal line of second main surface 30a. In heat-treating step S4, described later, first substrate 10 and second substrate 30 are held so that, for example, the c-axis direction and a-axis direction of first superconducting layer 20 are along the c-axis direction and a-axis direction of second superconducting layer 40, respectively.

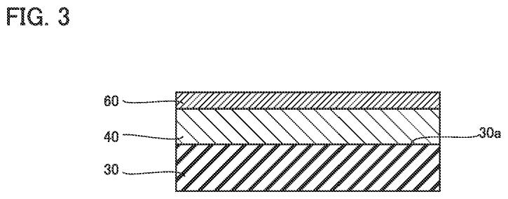

FIG. 3 is a sectional view of second substrate 30 after performing fine crystal layer forming step S3. As illustrated in FIG. 3, a fine crystal layer 60 is formed in fine crystal layer forming step S3. Fine crystal layer 60 is formed on second superconducting layer 40. Fine crystal layer 60 is formed of a polycrystal REBCO. Fine crystal layer 60 may be formed on first superconducting layer 20. That is, it suffices that fine crystal layer 60 is formed on any one of first superconducting layer 20 or second superconducting layer 40.

For forming fine crystal layer 60, an organic compound film is firstly formed on second superconducting layer 40 by, for example, a spin-coating method. This organic compound film contains the constituent elements of the REBCO. Secondly, the organic compound film is pre-calcined. This pre-calcining allows the organic compound film to be a REBCO precursor. Hereinafter, the pre-calcined organic compound film is referred to as a pre-calcined film. Thirdly, the pre-calcined film is heat-treated after the pre-calcining. This decomposes a carbide contained in the pre-calcined film to form fine crystal layer 60 that contains fine crystals of the REBCO.

In heat-treating step S4, barrier layer 50 is formed. In heat-treating step S4, first substrate 10 and second substrate 30 are heated in a state where first substrate 10 and second substrate 30 are held so that fine crystal layer 60 is sandwiched between first superconducting layer 20 and second superconducting layer 40. According to this, the REBCO contained in fine crystal layer 60 is epitaxially grown from first superconducting layer 20 and second superconducting layer 40 to form barrier layer 50. The heating in heat-treating step S4 is performed in an atmosphere that contains oxygen.

During heat-treating step S4, at least part of fine crystal layer 60 may form a liquid phase. A melting point of the REBCO that constitutes fine crystal layer 60 is lowered by reducing an oxygen concentration in the atmosphere in which the heating is performed. Thus, regulating the oxygen concentration in the atmosphere in which the heating is performed can form at least part of fine crystal layer 60 into a liquid phase during heat-treating step S4.

A heating temperature in heat-treating step S4 is, for example, 800° C. The oxygen concentration in the atmosphere in which the heating is performed in heat-treating step S4 is, for example, 60 ppm when at least part of fine crystal layer 60 is formed into a liquid phase. When fine crystal layer 60 is not formed into a liquid phase, the oxygen concentration in the atmosphere in which the heating is performed in heat-treating step S4 is 150 ppm, for example. A heating time in heat-treating step S4 is, for example, 1 minute when at least part of fine crystal layer 60 is formed into a liquid phase. When fine crystal layer 60 is not formed into a liquid phase, the heating time in heat-treating step S4 is 10 minutes, for example.

Second substrate 30 may be removed after heat-treating step S4 is performed. By the above steps, joined body 100 that has the structure illustrated in FIG. 1 is produced.

### <Effect of Joined Body 100>

Hereinafter, an effect of joined body 100 will be described with comparing a joined body according to Comparative Example. Hereinafter, the joined body according to Comparative Example is referred to as a joined body 200.

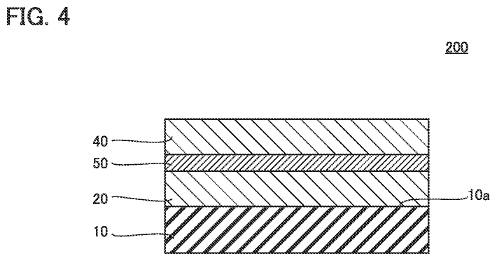

FIG. 4 is a sectional view of joined body 200. As illustrated in FIG. 4, joined body 200 has a first substrate 10, a first superconducting layer 20, a second superconducting layer 40, and a barrier layer 50, as in joined body 100.

However, in a step of producing joined body 200, barrier layer 50 is firstly epitaxially grown on first substrate 10, and second superconducting layer 40 is secondly formed on barrier layer 50.

Since the thickness of second superconducting layer 40 is larger than the thickness of barrier layer 50, a step of producing joined body 200 requires heating for a long time for forming second superconducting layer 40, and the rare earth element in first superconducting layer 20 and the rare earth element in second superconducting layer 40 diffuse into barrier layer 50. As a result, the REBCO that constitutes barrier layer 50 partially has superconductivity to flow the leak current between first superconducting layer 20 and second superconducting layer 40. That is, in joined body 200, pinholes are formed in barrier layer 50 to flow the leak current between first superconducting layer 20 and second superconducting layer 40.

On the other hand, in the step of producing joined body 100, heating for forming second superconducting layer 40 is not performed after forming barrier layer 50. Thus, heating in forming second superconducting layer 40 prevents diffusion of the rare earth element in first superconducting layer 20 and the rare earth element in second superconducting layer 40 into barrier layer 50 to form pinholes in barrier layer 50. Thus, according to joined body 100, barrier layer 50 can block the leak current between first superconducting layer 20 and second superconducting layer 40.

When at least part of fine crystal layer 60 forms a liquid phase during heat-treating step S4, the time required for forming barrier layer 50 is further shortened. Thus, this case further certainly prevents the diffusion of the rare earth element in first superconducting layer 20 and the rare earth element in second superconducting layer 40 into barrier layer 50 to cause the REBCO that constitutes barrier layer 50 to have superconductivity.

### Modified Example

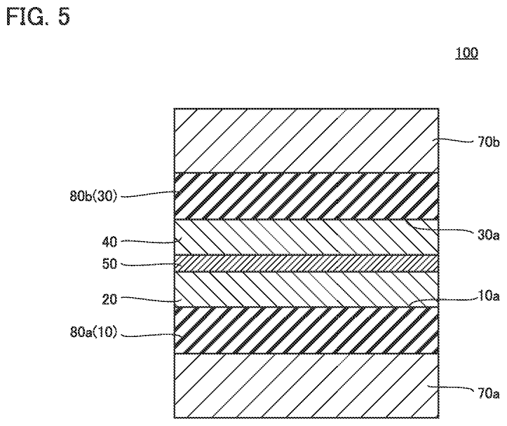

FIG. 5 is a sectional view of a joined body 100 according to a modified example. As illustrated in FIG. 5, joined body 100 may further comprise a first metal substrate 70a and a second metal substrate 70b. First metal substrate 70a and second metal substrate 70b are clad materials in which stainless steel, copper, and nickel are stacked, for example. In this example, first substrate 10 and second substrate 30 function as a first intermediate layer 80a and a second intermediate layer 80b. First intermediate layer 80a and second intermediate layer 80b are arranged on first metal substrate 70a and second metal substrate 70b, respectively. Joined body 100 may not comprise second metal substrate 70b and second intermediate layer 80b.

### Second Embodiment

A joined body according to the second embodiment will be described. Points that differ from joined body 100 are mainly described, and an overlapping description is not repeated. Hereinafter, the joined body according to the second embodiment is referred to as a joined body 300.

### <Constitution of Joined Body 300>

Hereinafter, constitution of joined body 300 will be described.

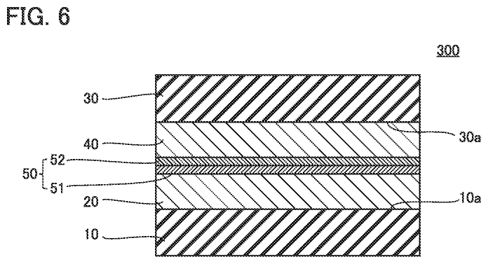

FIG. 6 is a sectional view of joined body 300. As illustrated in FIG. 6, joined body 300 has a first substrate 10, a first superconducting layer 20, a second substrate 30, a second superconducting layer 40, and a barrier layer 50. Regarding this point, the constitution of joined body 300 is in common with the constitution of joined body 100.

However, the constitution of joined body 300 differs from the constitution of joined body 100 regarding a detail of first superconducting layer 20, second superconducting layer 40, and barrier layer 50.

In joined body 300, the c-axis direction of the REBCO that constitutes second superconducting layer 40 is along the c-axis direction of the REBCO that constitutes first superconducting layer 20, as in joined body 100. However, in joined body 300, the a-axis direction of the REBCO that constitutes second superconducting layer 40 differs from the a-axis direction of the REBCO that constitutes first superconducting layer 20.

In joined body 300, barrier layer 50 has a first layer 51 and a second layer 52. First layer 51 is epitaxially grown from first superconducting layer 20. Second layer 52 is epitaxially grown from second superconducting layer 40. As noted above, in joined body 300, the a-axis direction of the REBCO that constitutes second superconducting layer 40 differs from the a-axis direction of the REBCO that constitutes first superconducting layer 20, and thereby the a-axis direction of the REBCO that constitutes first layer 51 differs from the a-axis direction of the REBCO that constitutes second layer 52. That is, in joined body 300, the lattices are not matched on an interface between first layer 51 and second layer 52.

In joined body 300, the rare earth element in the REBCO that constitutes barrier layer 50 may be selected so that barrier layer 50 exhibits superconductivity. That is, in joined body 300, the rare earth element in the REBCO that constitutes first superconducting layer 20, second superconducting layer 40, and barrier layer 50 may be at least one or more elements selected from the group consisting of yttrium, lanthanum, neodymium, samarium, europium, gadolium, dysprosium, holmium, erbium, thulium, lutetium, and ytterbium. In joined body 300, the rare earth element in the REBCO that constitutes barrier layer 50 may be praseodymium.

### <Method for Producing Joined Body 300>

Hereinafter, a method for producing joined body 300 will be described.

The method for producing joined body 300 comprises: a first substrate preparing step S1; a second substrate preparing step S2; a fine crystal layer forming step S3; and a heat-treating step S4. Regarding this point, the method for producing joined body 300 is in common with the method for producing joined body 100.

However, in second substrate preparing step S2 in the method for producing joined body 300, second superconducting layer 40 is formed so that the a-axis direction of second superconducting layer 40 differs from the a-axis direction of first superconducting layer 20. In heat-treating step S4 in the method for producing joined body 300, first layer 51 is epitaxially grown from first superconducting layer 20 and second layer 52 is epitaxially grown from second superconducting layer 40 to form barrier layer 50. Regarding these points, the method for producing joined body 300 differs from the method for producing joined body 100.

### <Effect of Joined Body 300>

In joined body 300, the a-axis direction of the REBCO that constitutes first layer 51 differs from the a-axis direction of the REBCO that constitutes second layer 52, and thereby a superconductive current that flows through first superconducting layer 20 cannot pass between first layer 51 and second layer 52. Similarly, a superconductive current that flows through second superconducting layer 40 also cannot pass between first layer 51 and second layer 52. Therefore, joined body 300 can also block the leak current between first superconducting layer 20 and second superconducting layer 40 by barrier layer 50.

The embodiments disclosed herein are examples at all points, and should be considered to be non-restrictive. The scope of the present invention is worded not by the above embodiments but by the claims, and intended to include meanings equivalent to the claims and all modification in the claims.

### REFERENCE SIGNS LIST

10 FIRST SUBSTRATE, 10a FIRST MAIN SURFACE, 20 FIRST SUPERCONDUCTING LAYER, 30 SECOND SUBSTRATE, 30a SECOND MAIN SURFACE, 40 SECOND SUPERCONDUCTING LAYER, 50 BARRIER LAYER, 51 FIRST LAYER, 52 SECOND LAYER, 60 FINE CRYSTAL LAYER, 70a FIRST METAL SUBSTRATE, 70b SECOND METAL SUBSTRATE, 80a FIRST INTERMEDIATE LAYER, 80b SECOND INTERMEDIATE LAYER, 100, 200, 300 JOINED BODY, S1 FIRST SUBSTRATE PREPARING STEP, S2 SECOND SUBSTRATE PREPARING STEP, S3 FINE CRYSTAL LAYER FORMING STEP, S4 HEAT-TREATING STEP

1. A joined body, comprising:
a first superconducting layer;
a barrier layer arranged on the first superconducting layer; and
a second superconducting layer arranged on the barrier layer, wherein
the first superconducting layer, the barrier layer, and the second superconducting layer are formed of a REBCO, and
a leak current from one of the first superconducting layer and the second superconducting layer to the other of the first superconducting layer and the second superconducting layer is blocked by the barrier layer.

2. The joined body according to claim 1, wherein
a rare earth element in the REBCO that constitutes the first superconducting layer and the second superconducting layer is selected so that the first superconducting layer and the second superconducting layer exhibit superconductivity, and
a rare earth element in the REBCO that constitutes the barrier layer is selected so that the barrier layer does not exhibit superconductivity.

3. The joined body according to claim 2, wherein
the rare earth element in the REBCO that constitutes the first superconducting layer and the second superconducting layer is at least one or more elements selected from the group consisting of yttrium, lanthanum, neodymium, samarium, europium, gadolinium, dysprosium, holmium, erbium, thulium, lutetium, and ytterbium, and
the rare earth element in the REBCO that constitutes the barrier layer is praseodymium.

4. The joined body according to claim 2, wherein the barrier layer is epitaxially grown from the first superconducting layer and the second superconducting layer.

5. The joined body according to claim 1, wherein
the barrier layer has a first layer arranged on the first superconducting layer and a second layer arranged on the first layer,
a c-axis direction of a REBCO that constitutes the first layer is along a c-axis direction of a REBCO that constitutes the second layer, and
an a-axis direction of the REBCO that constitutes the first layer differs from an a-axis direction of the REBCO that constitutes the second layer.

6. The joined body according to claim 5, wherein
the first layer is epitaxially grown from the first superconducting layer,
the second layer is epitaxially grown from the second superconducting layer,
a c-axis direction of the REBCO that constitutes the first superconducting layer is along a c-axis direction of the REBCO that constitutes the second superconducting layer, and
an a-axis direction of the REBCO that constitutes the first superconducting layer differs from an a-axis direction of the REBCO that constitutes the second superconducting layer.

7. The joined body according to claim 5, wherein a rare earth element in the REBCO that constitutes the first superconducting layer, the second superconducting layer, and the barrier layer is at least one or more elements selected from the group consisting of yttrium, lanthanum, neodymium, samarium, europium, gadolinium, dysprosium, holmium, erbium, thulium, lutetium, and ytterbium.

8. The joined body according to claim 1, further comprising a substrate, wherein
the first superconducting layer is arranged on the substrate, and
the substrate is formed of at least one or more oxides selected from the group consisting of cerium oxide, yttria-stabilized zirconia, lanthanum manganate, sapphire, or strontium titanate.

9. The joined body according to claim 1, further comprising:
a metal substrate; and
an intermediate layer arranged on the meal substrate, wherein
the first superconducting layer is arranged on the intermediate layer, and
the intermediate layer is formed of at least one or more oxides selected from the group consisting of cerium oxide, yttria-stabilized zirconia, lanthanum manganate, sapphire, or strontium titanate.

10. The joined body according to claim 1, further comprising a substrate, wherein
the first superconducting layer is arranged on the substrate, and
a c-axis direction of the REBCO that constitutes the first superconducting layer is along a direction of a main surface of the substrate on a side of the first superconducting layer or along a direction of a normal line of the main surface.

11. A method for producing a joined body, comprising:
forming a first superconducting layer on a first substrate;
forming a second superconducting layer on a second substrate;
forming a fine crystal layer on any one of the first superconducting layer and the second superconducting layer; and
heating the first substrate and the second substrate in a state where the first substrate and the second substrate are held so that the fine crystal layer is sandwiched between the first superconducting layer and the second superconducting layer, wherein
the first superconducting layer and the second superconducting layer are formed of a REBCO, and
the fine crystal layer is formed of a polycrystal REBCO.

12. The method for producing a joined body according to claim 11, wherein in heating the first substrate and the second substrate, at least part of the fine crystal layer forms a liquid phase.
